(19) United States
(12) Patent Application Publication
(10) Pub. No.: US 2021/0333313 A1
(43) Pub. Date: Oct. 28, 2021

(54) SYSTEMS AND METHODS FOR USE IN HANDLING COMPONENTS

(71) Applicant: ELECTRO SCIENTIFIC INDUSTRIES, INC., Portland, OR (US)

(72) Inventors: Douglas Garcia, Portland, OR (US); Madhan Pachiyappan, Beaverton, OR (US); Deenadayala Choundappan, Tamil nadu (IN)

(21) Appl. No.: 17/273,695

(22) PCT Filed: Oct. 14, 2019
(86) PCT No.: PCT/US2019/056138

§ 371 Date: Mar. 4, 2021

Related U.S. Application Data
(60) Provisional application No. 62/745,777, filed on Oct. 15, 2018.

(51) Int. Cl. G01R 31/01; B07C 5/344; B07C 5/36

(52) U.S. Cl. CPC G01R 31/016; B07C 5/361; B07C 5/363; B07C 5/344

(57) ABSTRACT

An electrical component testing apparatus can include a vacuum plate including a first surface, a second surface opposite the first surface, and through-holes extending through the vacuum plate from the first surface to the second surface. The apparatus also includes a manifold arranged at the second surface of the vacuum plate. The manifold can include a manifold body and passageways extending within the manifold body, wherein each of the passageways includes a first end and a second end. The first end includes an opening that intersects an exterior of the manifold body at a first location corresponding to a location of a through-hole in the vacuum plate and the second end includes an opening that intersects an exterior of the manifold body at a second location. The apparatus can also include a source of pressurized air coupled to the opening of the second end.

### CROSS-REFERENCE TO RELATED APPLICATIONS

This application claims the benefit of U.S. Provisional Application No. 62/745,777, filed Oct. 15, 2018, which is incorporated by reference in its entirety.

### BACKGROUND

### I. Technical Field

Embodiments discussed herein relate to systems and methods for handling electrical components.

### II. Discussion of the Related Art

Many electrical components such as passive or active circuit or electronic devices are tested for electrical and optical properties during manufacturing by automated test systems. Typical automatic sorting apparatuses use precision electrical or optical properties of the tested device and either accept, reject, or sort it into an output category depending on the measured values. For miniature devices, automatic sorting apparatuses are often designed to handle, bulk loads, where the manufacturing process creates a volume of devices that have substantially identical mechanical characteristics such as size and shape but differ in electrical or optical properties that generally fall within a range and rely on testing to sort the components into sort bins containing other components with similar characteristics.

### BRIEF DESCRIPTION OF THE DRAWINGS

FIG. 1 illustrates a perspective view of an electrical component handler according to one embodiment of the present invention.

FIG. 1a illustrates a perspective view of an example of a collection system for the electrical component handler shown in FIG. 1.

FIG. 3 illustrates a perspective view of various components of the electrical component handler shown in FIG. 1, as well as a test plate that may be used with the electrical component handler.

FIG. 4 illustrates a partial cross-sectional view of the test plate shown in FIG. 3, taken along a radial line extending medially through a row of component seats defined by the test plate.

FIG. 5 illustrates a perspective view of a loading structure of the electrical component handler shown in FIG. 1.

FIG. 5a illustrates a cross-sectional view taken along line 10a-10a shown in FIG. 5.

FIG. 6 illustrates a perspective view of an ejection manifold of the electrical component handler shown in FIG. 1.

FIG. 7 illustrates a cross-sectional view taken along line 12-12 of FIG. 3.

FIG. 8 illustrates a pictorial view of a component hopper assembly of the electrical component handler shown in FIG. 1.

FIG. 9 illustrates a perspective view of a spout of the component hopper assembly shown in FIG. 8.

FIG. 10 illustrates an arc suppression circuit according to one embodiment, which may be incorporated within the electrical component handler shown in FIG. 1.

FIGS. 11, 12, 13 and 14 illustrate various perspective views of a manifold, according to one embodiment, which may be used with the electrical component handler shown in FIG. 1.

FIG. 15 illustrates a perspective view showing an arrangement of decelerators integrally formed in a common decelerator body, according to one embodiment, which may be used with the electrical component handler shown in FIG. 1.

FIG. 16 illustrates a perspective view showing a decelerator integrally formed in the common decelerator body shown in FIG. 15.

### SUMMARY

One embodiment of the present invention may be characterized as an electrical component testing apparatus. The apparatus includes a vacuum plate including a first surface; a second surface opposite the first surface; and a plurality of through-holes extending through the vacuum plate from the first surface to the second surface. The apparatus also includes a manifold arranged at the second surface of the vacuum plate. The manifold can include a manifold body and a plurality of passageways extending within the manifold body, wherein each of the plurality of passageways includes a first end and a second end. The first end includes an opening that intersects an exterior of the manifold body at a first location corresponding to a location of a through-hole in the vacuum plate and the second end includes an opening that intersects an exterior of the manifold body at a second location. The apparatus can also include a source of pressurized air coupled to the opening of the second end.

Another embodiment of the present invention may be characterized as a decelerator for an electrical component testing apparatus having a tube assembly with a first end and a second end opposite the first end, wherein the second end is lower than the first end, wherein the first end is configured to receive a plurality of electrical components and the tube assembly is configured such that received electrical components can travel therethrough along a path of travel. The decelerator may include: a decelerator body having an opening formed therein, the opening having a first end as a second end opposite the first end; and a decelerator arranged within the opening. The decelerator includes a decelerator body having an opening formed therein, the opening having a first end as a second end opposite the first end; and a structure defining a convex surface within the opening and facing toward first end of the opening; and a concave surface arranged below the structure.

### DETAILED DESCRIPTION

Example embodiments are described herein with reference to the accompanying drawings. Unless otherwise expressly stated, in the drawings the sizes, positions, etc., of components, features, elements, etc., as well as any distances therebetween, are not necessarily to scale, but are exaggerated for clarity. In the drawings, like numbers refer to like elements throughout. Thus, the same or similar numbers may be described with reference to other drawings even if they are neither mentioned nor described in the corresponding drawing. Also, even elements that are not denoted by reference numbers may be described with reference to other drawings.

The terminology used herein is for the purpose of describing particular example embodiments only and is not intended to be limiting. Unless otherwise defined, all terms (including technical and scientific terms) used herein have the same meaning as commonly understood by one of ordinary skill in the art. As used herein, the singular forms “a,” “an” and “the” are intended to include the plural forms as well, unless the context clearly indicates otherwise. It should be recognized that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Unless otherwise specified, a range of values, when recited, includes both the upper and lower limits of the range, as well as any sub-ranges therebetween. Unless indicated otherwise, terms such as “first,” “second,” etc., are only used to distinguish one element from another. For example, one node could be termed a “first node” and similarly, another node could be termed a “second node”, or vice versa.

Unless indicated otherwise, the term “about,” “thereabout,” “approximately,” etc., means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. Spatially relative terms, such as “below,” “beneath,” “lower,” “above,” and “upper,” and the like, may be used herein for ease of description to describe one element or feature's relationship to another element or feature, as illustrated in the FIGS. It should be recognized that the spatially relative terms are intended to encompass different orientations in addition to the orientation depicted in the FIGS. For example, if an object in the FIGS. is turned over, elements described as “below” or “beneath” other elements or features would then be oriented “above” the other elements or features. Thus, the exemplary term “below” can encompass both an orientation of above and below. An object may be otherwise oriented (e.g., rotated 90 degrees or at other orientations) and the spatially relative descriptors used herein may be interpreted accordingly.

The section headings used herein are for organizational purposes only and, unless explicitly stated otherwise, are not to be construed as limiting the subject matter described. It will be appreciated that many different forms, embodiments and combinations are possible without deviating from the spirit and teachings of this disclosure and so this disclosure should not be construed as limited to the example embodiments set forth herein. Rather, these examples and embodiments are provided so that this disclosure will be thorough and complete, and will convey the scope of the disclosure to those skilled in the art.

### I. OVERVIEW

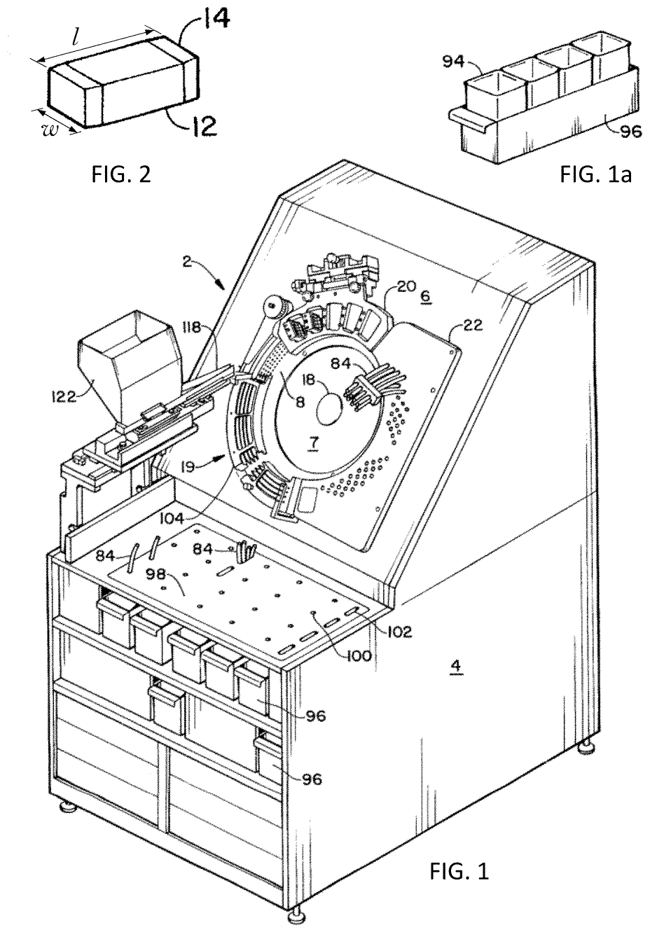

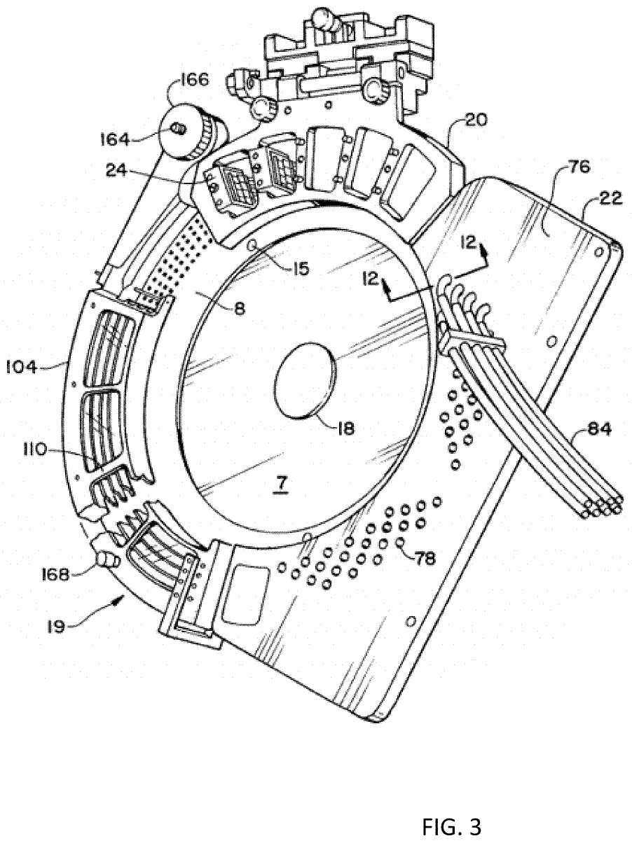

Referring to FIGS. 1 and 3, an electrical component handler (also referred to herein as a “handler”), generally designated 2, is illustrated to have a supporting structure 4 having planar inclined surface 6 (e.g., inclined at an angle of 45°, 60°, 75°, 90°, etc., or between any of these values). Extending through a hole defined by the inclined surface, is a turntable 7, likewise inclined, for rotating a disk-like test plate 8. The test plate 8 is in the form of a flat ring and defines a plurality of rows or tracks of open component seats 10. The seats are designed to match the components that they are expected to seat. In the illustrated embodiment, each seat 10 includes a through-hole and is sized to freely seat and hold a component 12 (see, e.g., FIG. 2) only when the component's “terminal axis” is aligned with the seat, within a tolerance. The terminal axis is an axis of the component 12 running through its opposing terminals 14, and when so seated, one of the terminals 14 protrudes above the face 16 of the test plate 8 for being contacted from above, and the other terminal 14 is exposed at the base of the seat for being contacted from below. Preferably the seats have a profile similar to that of their intended components, as viewed along the terminal axis, but are slightly larger than the components so that they can accept components entering at angles within a range of entry angles. The range of entry angles depends on how much lateral space can be tolerated between the components and the seat walls. As illustrated, each test plate row is a line of four radially spaced component seats, and the rows are uniformly angularly spaced around the test plate, forming four concentric rings of seats.

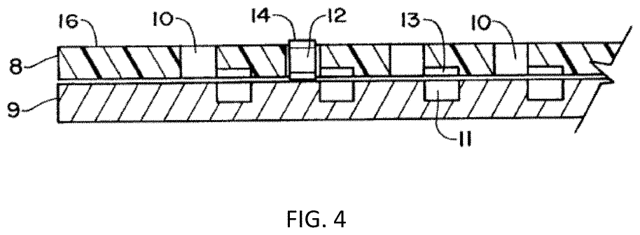

Referring to FIG. 4, beneath the component seat rings is a stationary “vacuum” plate 9 which supports the seated components. The vacuum plate is preferably, but not necessarily, a steel ring having a flat upper face that is chrome-plated to minimize friction between the stationary upper face and the moving components, and to minimize wear on the vacuum plate. The upper face of the vacuum plate defines a plurality of annular vacuum channels 11. There is a vacuum channel adjacent and concentric with each component seat ring. As illustrated for this embodiment, there are four vacuum channels, one inboardly adjacent to each seat ring. The vacuum channels are all coupled to a low pressure source (low relative to ambient pressure) so that during operation the vacuum channels communicate a partial vacuum to a plurality of linking channels 13 defined in the bottom of the test plate. These linking channels communicate the partial vacuum from the vacuum channels to the component seats. There is a linking channel communicating, one for one, with each component seat. By this arrangement components are urged into the seats and held there by the partial vacuum in the vacuum channels communicated to the seats via their respective linking channels.

The test plate 8 partially rests upon the turntable 7 and is properly located thereon by a plurality of locator pins 15 that mate with locator holes 17 defined near the inner rim of the test plate. As illustrated, the test plate 8 is rotatable clockwise around a turntable hub 18. As the test plate 8 turns, the component seats pass beneath a loading area generally designated 19, a contactor assembly 20, and an ejection manifold 22. As will be explained below, the components are deposited in test plate seats at the loading area and are thereafter rotated beneath the contactor assembly where each component is electrically contacted and parametrically tested.

Referring to FIG. 3, to allow the test plate to be rotated at an optimum angular speed but yet ensure that each seated component gets thoroughly tested, the contactor assembly includes multiple spaced contactor modules 24 (e.g., five contactor modules 24), each of which has an upperside contact (not shown) in line with each ring of component seats. Since in this embodiment there are four seat rings and the contactor assembly 20 can accommodate five contactor modules 24, there are five upperside contacts per ring of seats. On the opposite side of the test plate and in registration with the upperside contacts, one each, are twenty underside contacts 23. So if a handler according to this embodiment has a full complement of contactor modules (which need not be the case), the terminals of twenty seated components can be contacted simultaneously, thereby simultaneously coupling all twenty individually to a tester.

The five contactor modules 24, and their corresponding underside contacts, can be used as five separate testing stations. This is particularly advantageous for testing ceramic capacitors which are often conventionally subjected to five stages of testing. During a typical first stage the capacitance and dissipation factor of the components are tested. A typical second stage test, commonly called a “flash” test, involves applying a high voltage (typically 2-2½ times the component's voltage rating) for a short time (typically 40-50 ms). During a typical third stage test a low voltage (e.g. 50 v) is applied for testing the leakage current or insulation resistance. During a typical fourth stage test, the component's rated voltage is applied to it for a soaking period (typically 100s of ms) and leakage/insulation resistance is again tested. During a typical fifth stage test, the capacitance of the component is again tested to see if it has been affected by the other tests. A first contactor module encountered by the components in the direction of test plate rotation can be used to apply the first stage test to each passing row. The second contactor module encountered can be used to apply the second stage test to each row, and so on. In this way the five tests can be overlapped in time to at least some extent.

It should be understood that more than four seat rings (e.g., eight seat rings) in which case the contactor modules would correspondingly have more than four upperside contacts. Likewise the techniques discussed herein can be implemented with less than four seat rings, in which case the contactor modules would correspondingly have less than four upperside contacts. Moreover, embodiments of the present invention can be implemented with more than five, or less than, five contactor modules. In all cases there would be an equal number of underside contacts in registration with the upperside contacts.

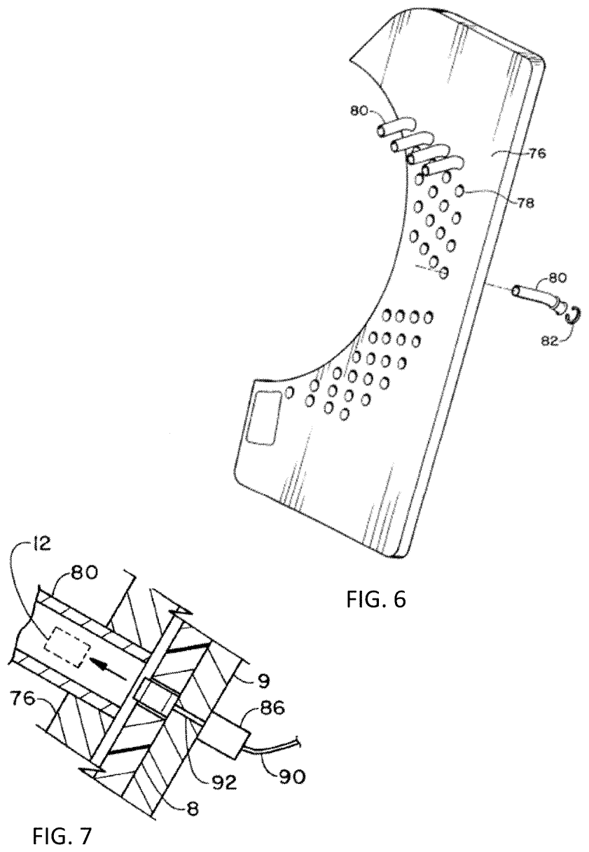

Referring to FIGS. 3 and 6, after being tested, the components are indexed beneath the ejection manifold 22 which, as illustrated, includes a manifold plate 76 defining a plurality of ejection manifold through-holes 78 which register with component seats as the seats are indexed beneath. The ejection manifold through-holes 78 are sized to accommodate, one each, tube couplers 80 which are slightly bent, rigid tubes which mate with the ejection manifold through-holes 78 and are secured therein by, for example, snap rings 82. The tube couplers 80 are sized in inner diameter to freely accommodate the passage therethrough of ejected components 12. As will be explained in more detail, the components 12 are ejected from their seats 10 by a blast of air from beneath/behind the seats, and the air forces them to pass through the tube couplers 80 into respective ejection tubes 84 connected to the tube couplers 80. Although only eight ejection tubes are illustrated, it should be understood that any number, including all, of the ejection manifold through-holes 78 can have an ejection tube coupled thereto, by means of a tube coupler 80, for communicating tested components to sorting bins.

Referring to FIG. 7, directly beneath/behind the vacuum plate 9 are a plurality of selectively actuated pneumatic valves 86, or flexible tubes from such valves located elsewhere, connected to a source of pressurized air via tubes 90. The valves 86 (or tubes from the valves 86) are in registration, one each, with the ejection manifold through-holes 78. Thus each time the test plate 8 is indexed, a set of component seats 10 are brought into registration with, and between, the ejection manifold through-holes 78 and the pneumatic valves 86. The vacuum plate 9 defines through-holes 92 also in registration with the pneumatic valves 86. Thus each component seat 10 in registration with an ejection manifold through-hole 78 is in an air communication path between the ejection manifold through-hole 78 and a respective pneumatic valve 86, and actuation of the pneumatic valve 86 will cause a component 12 residing in the seat 10 to be forced upward from the seat 10 and through the ejection manifold through-hole 78 by the air pressure. The air pressure will also drive the component 12 through a respective tube coupler 80 and into the ejection tube 84 connected to the tube coupler 80. These bursts of air are of sufficient pressure to overcome the effect of the partial vacuum communicated by the vacuum channels 11. By this arrangement, selected components 12 can be ejected from their seats by selective actuation of the pneumatic valves 86 beneath them. Thus the components 10 in a seat ring can be selectively ejected into any ejection tube 84 aligned with the ring.

Referring to FIGS. 1 and 1a, the ejected components 12 traverse their respective ejection tubes 84, propelled by the bursts of air and gravity, to be deposited in sorting bins 94. As illustrated the bins are carried by bin trays 96, four bins per tray. To collect tested components, the trays of bins are placed on shelves beneath and in front of the ejection manifold 22. The open ends of the tubes (the ends remote from the ejection manifold) are routed to their proper bins by a tube routing plate 98 which defines a plurality of through-holes 100 and through-slots 102. The holes and slots are located to be centrally disposed above their corresponding sorting bins. The holes are sized to accept one ejection tube each, and the slots are sized to accept four tubes each. The open ends of the tubes are inserted into the holes or slots to guide components to their bins below. Although FIG. 1 illustrates, for clarity, only a few broken segments of ejection tubes 84 connected to the ejection manifold 22 and a few broken segments of ejection tubes protruding from the tube routing plate 98, it should be understood that all the ejection tubes 84 are actually continuous, i.e. uninterrupted and unbroken, in their runs from the manifold plate 76 to the tube routing plate 98 and to the corresponding bins below. It should also be understood that all or some portion, as desired, of the ejection manifold through-holes 78 have tubes running to the tube routing plate 98.

Referring to FIGS. 1, 3, 5, 5a and 9, the components 12 are distributed into the test plate seats in the loading area 19 which lies beneath a stationary, arcuate loading frame 104. The loading frame has a containment wall 106 and a plurality of seating fences, illustrated as four walls, 108a-108d, matching in number the four component seat rings. The seating fences are of uniform height and are connected remote from the test plate by cross members 110. The arcs of the seating fences are concentric with the seat rings and there is one seating fence immediately adjacent the outboard side of each seat ring. The bases of the seating fences are slightly spaced above the test plate, for example by shims, so as to prevent passing or catching of components beneath the fences. Preferably the fences extend from about the nine o'clock position of the test plate (using the hour points of a clock as position indicators) to about the five o'clock position. As illustrated, at the nine o'clock end of the loading frame, the gaps between the fences, 110a-110d, are open to serve as mouths for insertion of components in the gaps. In another embodiment, however, the gaps between the fences, 110a-110d, can be open at the six, or seven o'clock positions along the loading frame, to serve as mouths for insertion of components. In operation, components to be tested are poured into the gaps in generally equal proportions, and as the components fall downward they are distributed and tumble along the seating fences by gravity. Distribution can be further assisted by use of an air knife 112 having a plurality of forced air nozzles, one directed into each gap between the fences. As illustrated, the test plate 8 turns in the clockwise direction and due to gravity each unseated component continuously tumbles in the opposite direction, along a seating fence, over empty seats passing through an arc of the ring's rotation path until it is eventually seated. Once in the seats, they are held therein by partial vacuum communicated to the seats from annular vacuum channels (not shown).

Referring to FIGS. 1, 8 and 9, the components 12 to be tested are poured into the gaps, 110a-110d, between the seating fences by an open top funnel 114 having a mouth 116 the width of which matches the gaps between the fences. As will be explained below, the funnel can be selectively positioned squarely over each of the four gaps so as to pour components primarily into the selected gap. The funnel receives a stream of components 12 from a stationary feeder tray 118 which is mounted on a shaker 120. The feeder tray preferably is gravity fed quantities of components from a hopper 122 and, when activated, the shaker 120 vibrates the feeder tray 118 to move the components to the funnel. The hopper has a large input mouth 124 which funnels the components to the feeder tray 118. The spacing of the output mouth (not shown) of the hopper above the tray effectively meters the components to the tray. A portion 126 of the floor of the feeder tray is perforated by uniformly sized holes, and below the perforated portion is a catch tray 128. The perforations are to filter out undersized components which will pass through the perforations and be caught by the catch tray below. The perforated portion is preferably a mesh.

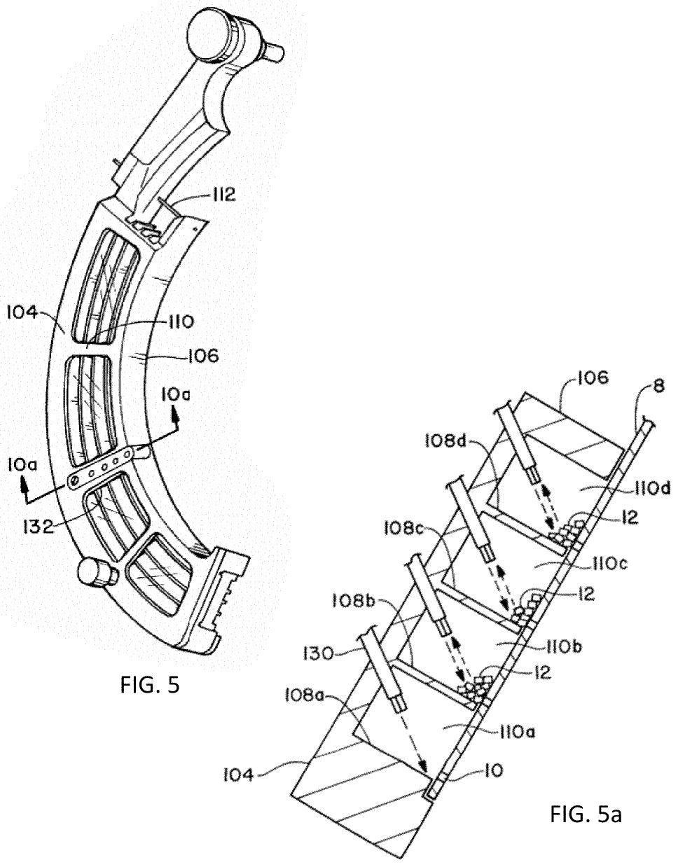

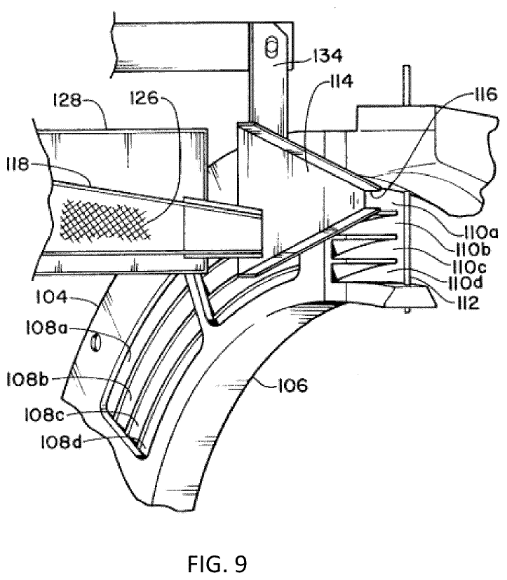

Referring to FIGS. 5, 5a and 9, the position of the funnel 114 over the gaps, 110a-110d, is controlled by a controller (not shown) that determines which gap or gaps are in need of components 12. The controller receives signals from a plurality of component sensors 130, one per gap, disposed in respective angular holes defined by a loading frame cross member 132. The sensors each include a pair of fiber optic cables, one cable coupled to a coherent light source, such as a laser beam generator, and the other cable coupled to a photodetector. The holes are angled such that the free ends of the optic cables are aimed at the downhill corners of the gaps, i.e., the corners in which the components should collect due to gravity, as best illustrated in FIG. 5a. The components are typically light reflective. The dashed arrows of FIG. 5a pointing to the downhill corners represent light beams being emitted by the sensors, and the dashed arrows in reverse represent those portions of the reflected light that impinge the sensors.

In operation, each sensor 130 directs a light beam toward the downhill corner of its gap, and if there are no components present in the corner (as in gap 110a of FIG. 5a), then the beam will not be reflected or be reflected to a much lesser degree than if components were present (as in gaps 110b-110d of FIG. 5a). The lack of, or lesser, reflection is noted by the controller. If this condition persists over a predetermined period of time, the controller will then actuate a step motor (not shown) which drives an arm 134 to position the mouth of the funnel over the gap in need of components. When the handler is operating, this process of checking the gaps and moving the funnel is continuous. In this manner components are distributed to the gaps in generally equal proportions. It has been found that, by locating the sensors at about the seven o'clock position with respect to the test plate, they are in an optimum position for sensing the absence of components.

Referring to FIG. 3, the loading frame 104 can be rotated on a pivot pin 164 away from the test plate 8 and can be locked into place by a thumb screw 166 and locking pin 168. This facilitates installation and replacement of test plates.

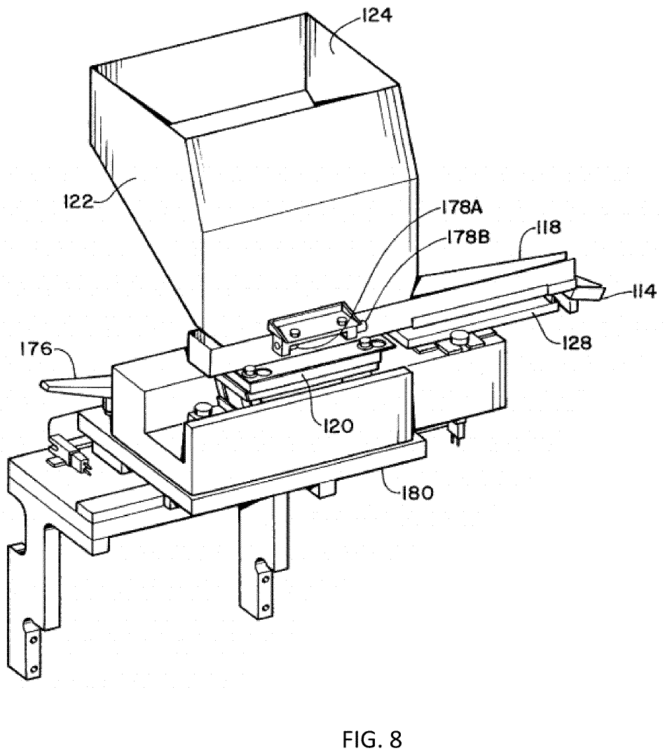

Referring to FIG. 8, the hopper 122, feed tray 118 and funnel 114 can all be slid back along guides to also facilitate installation and replacement of test plates. They and the shaker 120 are all mounted on a slidable plate 180 which slides on bearing guides below. The plate is locked in place for operation by a lever 176 connected to a locking mechanism (not shown). Also, the hopper can be dumped by releasing a lock (not shown) and pushing it forward to engage a bracket affixed to a hopper wall with two pivot pins, 178A and 178B affixed to the feeder tray 118 wall. Once the pins are engaged the hopper can be rotated on them to spill the contents of the hopper.

Additional information concerning the handler 2 can be found in U.S. Pat. No. 5,842,579, which is attached as an appendix at the end of this application.

### II. EMBODIMENTS CONCERNING HIGH-RATE COMPONENT LOADING

As mentioned above, the process of checking the gaps and moving the funnel 114 is continuously performed during operation of the handler 2. However, the funnel 114 is generally not moved continuously. Rather, the arm 134 moves the funnel 114 according to a “stop-and-go”control mode. According to the “stop-and-go” control mode, the funnel 114 is moved over a gap in need of components 12. After the funnel 114 arrives over a gap in need of components 12, movement of the funnel 114 is stopped and, while the funnel 114 is stationary, components 12 are fed from the hopper 122 to the funnel 114 (i.e., via the feeder tray 118) by activating the shaker 120. After components 12 have been fed to the funnel 114 (e.g., for a predetermined amount of time), the components 12 are poured from the funnel 114 into the gap in need of components 12 (e.g., under the influence of gravity). After the components 12 are poured into the gap in need of components 12, the funnel 114 can be moved over another gap in need of components 12 and the above process can be repeated.

The “stop-and-go” control mode of loading works well for relatively small-sized components 12 (e.g., MLCC chips smaller than the 0805 chip size (i.e., 2 mm in length, 1.25 mm in width)), but when components 12 to be loaded into the loading area 19 are larger than the 0805 chip size, it can take an unacceptably long time for the relatively large-sized components 12 to be fed from the hopper 122 to the funnel 114 (i.e., by activating the shaker 120 to vibrate the feeder tray 118). As a result, the efficiency with which the relatively large-sized components 12 can be poured into the gap in need of components 12 (i.e., the gap-filling efficiency) can be unacceptably low.

To increase the gap-filling efficiency, the funnel 114 can be moved according to a “continuous” control mode. According to the “continuous” control mode, the rate with which components 12 are fed into a gap from the funnel 114 is controlled by controlling the intensity with which the feeder tray 118 is vibrated (i.e., by the shaker 120). In this case, the controller may control the operation of the shaker 120 (e.g., by outputting a pulse width modulation signal to the shaker 120). The controller uses information generated by the component sensors 130 to control the movement of the funnel 114 and the operation of the shaker 120. For example, if a gap feeding components 12 to one track on the test plate 8 needs more components 12, then the funnel 114 will be moved relatively slowly over the gap. Likewise, if a gap feeding components 12 to one track on the test plate 8 needs fewer components 12, then the funnel 114 will be moved relatively quickly over the gap.

Light from the light beam directed by sensor 130 is not uniformly reflected by the components 12 (especially when the components 12 are relatively large-sized components 12), so the reflected-light signal will have lots of high-frequency noise. A sliding timing window can be used to capture the reflected-light signal and, within the sliding timing window, a pulse high and pulse low widths, can be used to estimate the number of components 12 in a gap.

When the funnel 114 is empty, the shaker 120 can be operated to vibrate the feeder tray 118 at the highest intensity. Thereafter, the shaker 120 can be operated to vibrate the feeder tray 118 at a lower intensity, which may optionally be variable depending upon the information generated by the sensor 130.

### III. EMBODIMENTS CONCERNING ARC SUPPRESSION

Charging components 12 such as large-capacity MLCC chips in conventional high-throughput electrical component handlers can yield repeated arcing of capacitor-to-handler contacts, resulting in pits (e.g., in upperside contacts of the contactor modules 24). Arc suppression is conventionally mitigated by forming the upperside contacts from hardened materials, and by making them replaceable. But, as storage capacitance need grows, the usefulness or effectiveness of these conventional techniques decreases.

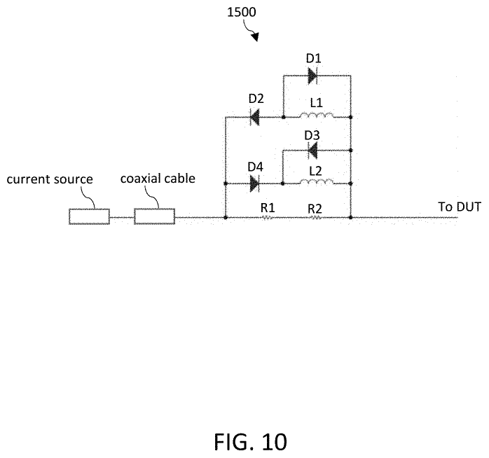

Accordingly, one embodiment addresses the aforementioned problems associated with arcing between the terminals 14 of components 12 and upperside contacts of contactor modules 24 by inserting an arc-suppression circuit into each of the contactor modules 24 at a location that is near the components 12 during testing. Referring to FIG. 10, an arc suppression circuit 1500 may be electrically connected between an upperside contact of a contactor module 24 and a first end of a cable. The cable may be provided as a coaxial cable many feet (e.g., 6 feet, or thereabout) in length. A second end of the cable, opposite the first end may be electrically connected to a current source. In the arc suppression circuit 1500, the values of the diodes D1, D2, D3 and D4, the values of the inductors L1 and L2, and the values of the resistors R1 and R2 may be selected or set depending upon one or more factors such as the magnitude of the current supplied by the current source, the capacitance of the components 12 to be tested at a contactor module 24, the desired (or required) charge and discharge time of the component 12 to be tested, or the like or any combination thereof. In one embodiment, R1, R2, L1 and L2 can be 200 ohm (or thereabout), 200 ohm (or thereabout) or 1000 ohm (or thereabout), 220 μH (or thereabout) and 220 pH (or thereabout), respectively.

The arc suppression circuit 1500 can provide for reduced capacitor charging time (thus resulting in increased testing throughput) and reduced pitting on contacts (e.g., upperside contacts), which can result in fewer required service operations over the lifetime of the handler.

### IV. EMBODIMENTS CONCERNING COMPONENT SORTING—MANIFOLD

As mentioned above, a plurality of selectively actuated pneumatic valves 86, or tubes from such valves located elsewhere, connected to a source of pressurized air via tubes 90, can be located directly beneath/behind the vacuum plate 9. As processing speeds become faster, the response of the pneumatic system needs to allow the air ejection cycle (which occurs within a “dwell” period of the overall sorting process) to be fast enough to not require a dwell time increase. Also, with processing speeds for components such as multi-layer ceramic capacitors currently at 1.2 million parts per hour, the pneumatic valves 86 require more frequent replacement. Easy replacement with good access to the pneumatic valves 86 is therefore desirable.

In an embodiment different from that illustrated in FIG. 7, the pneumatic valves 86, or flexible tubes from such valves, may be replaced with an air-distribution manifold provided directly beneath/behind the vacuum plate 9 (i.e., at the vacuum plate 9). Generally, the air-distribution manifold can be characterized as including a manifold body and a plurality of passageways. Each passageway may terminate at an exterior surface of the manifold body so as to define a first end (e.g., at a first location in the exterior surface of the manifold body) and a second end (e.g., at a second location in the exterior surface of the manifold body). The first end of each passageway intersects an exterior of the manifold at an opening that can coupled to a source of pressurized air, and the second end of each passageway intersects an exterior of the air-distribution manifold at an opening that can be coupled to a through-hole 92 extending through the vacuum plate 9. Fluid communication through a passageway, between the source of pressurized air and a through-hole 92, can be opened or closed using an air valve switching means (e.g., a solenoid valve) coupled to the air-distribution manifold (e.g., at the first end of the passageway).

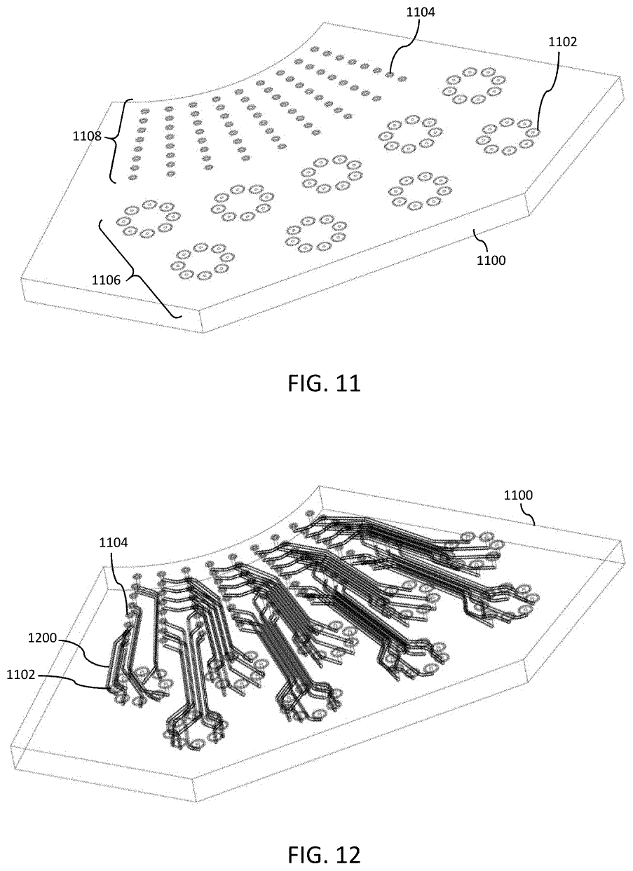

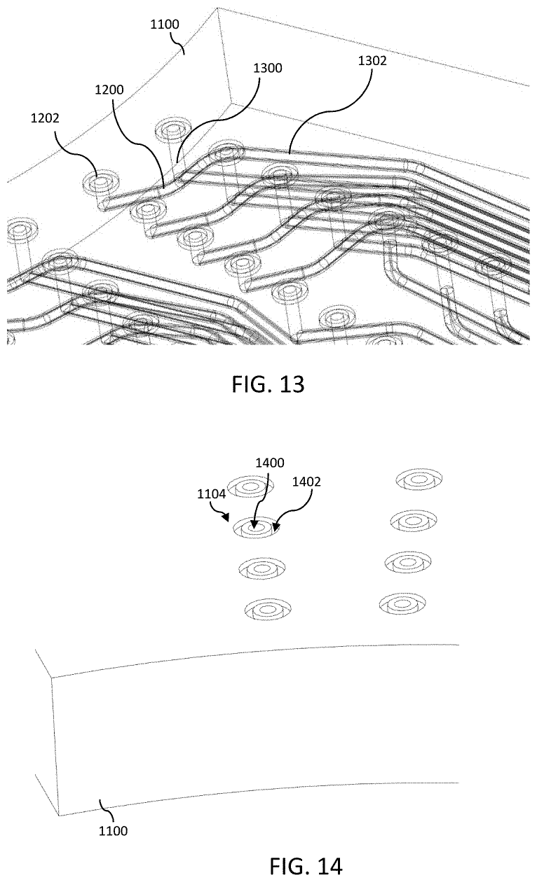

FIGS. 11, 12, 13 and 14 are various perspective views of an air-distribution manifold, according to one embodiment. Specifically, FIG. 11 illustrates an arrangement of the first and second ends of passageways as defined in the exterior surface of the manifold body. FIG. 12 illustrates an arrangement of passageways within the manifold body. FIG. 13 illustrates a close-up view of the arrangement of passageways through the manifold body shown in FIG. 12. FIG. 14 illustrate a close-up view of the second ends.

Referring to FIGS. 11, 12 and 13, the air-distribution manifold includes a manifold body 1100 and a plurality of passageways 1200 extending within the manifold body 1100. Each passageway 1200 can transmit pressurized air from a first end thereof (e.g., identified at 1102) to a second end thereof (e.g., identified at 1104). The first end 1102 of each passageway 1200 intersects an exterior surface of the manifold body 1100 at an opening that can coupled to a source of pressurized air. The second end 1104 of each passageway 1100 intersects the exterior surface of the manifold body 1100 at an opening that can be coupled to the vacuum plate 9.

As best shown in FIG. 11, the number and arrangement of first ends 1102 at the exterior surface of the manifold body 1100 (e.g., identified generally at 1106) can be provided in any suitable or desired manner. The number and arrangement of second ends 1104 at the exterior surface of the manifold body 1100 (e.g., identified generally at 1108) can correspond to the number and arrangement of through-holes 92 in the vacuum plate 9.

As best shown in FIG. 13, within the manifold body 1100, each passageway 1200 can be characterized as including a plurality of first portions 1300 (though, only one first portion 1300 of each passageway 1200 is shown) and a second portion 1302. Each first portion 1300 extends from the exterior surface of the manifold body 1100 into the manifold body 1100 to some predetermined depth. Each second portion 1302 extends between, and is in fluid communication with, a pair of first portions 1300, so as to allow fluid communication between the first end 1102 and the second end 1104. As also best shown in FIG. 13, the first portions 1300 of one or more passageways 1200 may extend deeper into the manifold body 1100 than the first portions 1300 of other passageways 1200. As a result, the second portions 1302 of one or more of the passageways 1200 may be further from the aforementioned exterior surface of the manifold body 1100 than the second portions 1302 of other passageways 1200.

Referring to FIG. 14, the second end 1104 of each passageway 1200 can include an opening 1400 (i.e., a portion of the passageway that intersects with the exterior of the manifold body 1100) and an annular channel 1402 around the opening. The annular channel 1402 can be sized so as to accommodate a seal (e.g., an O-ring, not shown) to facilitate secure communication with the vacuum plate 9. It will be appreciated that the first end 1102 of each passageway 1200 can be configured in a similar manner as the second end 1104 shown in FIG. 14.

The first ends 1102, second ends 1104 and passageways 1200 can be formed in the manifold body 1100 in any manner known in the art. For example, the manifold body 1100 can be provided as multiple polymeric plates. One or more plates may have holes (e.g., blind-holes or through-holes) formed therein (e.g., corresponding to the first portions 1300 of the passageways 1200). Likewise, one or more plates may have channels formed therein (e.g., extending from a surface thereof, such that the channels correspond to the second portions 1302 of the passageways 1200). The plates can be stacked upon one another and aligned such that holes formed in one plate are in fluid communication with holes or channels formed in one or more other plates. Thereafter, the plates can be bonded together (e.g., in a thermal fusion process, as is known in the art).

As best shown in FIGS. 11 and 12, the manifold body 1100 contains relatively short passageways 1200, allowing for fast pneumatic response times. The passageways 1200 are of uniform (or substantially uniform) length to reduce variation in pneumatic response of the air passageways, creating more predictable component ejection cycle timing.

In one embodiment, the manifold body can be made from a visually clear material (e.g., transparent), allowing the interior of the passageways to be visible and facilitating inspection of the passageways (e.g., to make sure there are no obstructions or contamination within the passageways). Forming the manifold body from a visually clear material also allows backlighting of the manifold, through to the system ejection ports which are adjacent to the components 12 to be ejected. This will allow visual confirmation as to whether the ejection ports are clean or not. Simple arrangement for mounting and locating the air valves for easy replacement, while still being very close to the component ejection ports (the “work”).

### V. EMBODIMENTS CONCERNING COMPONENT SORTING—DECELERATOR

When sorting small components 12 such as multi-layer ceramic capacitors at high speeds, they can be damaged due to the acceleration and velocity required to move them within a handling system at a sufficient rate. Deceleration means (e.g., rubber rods, a series of flaps, or the like or any combination thereof) can be provided in a final collection container (e.g., a bin tray 96) to slow down components 12 entering into the container. However, such deceleration means can interfere with the removal of components 12 from the container. If components 12 are not reliably removed from the container, they could get mixed into the next lot of components that may be a different type. This is known as a “mixed lot” failure event. Also, once the deceleration means is covered or submerged due to the filling of the container by the components 12, there is no more deceleration function.

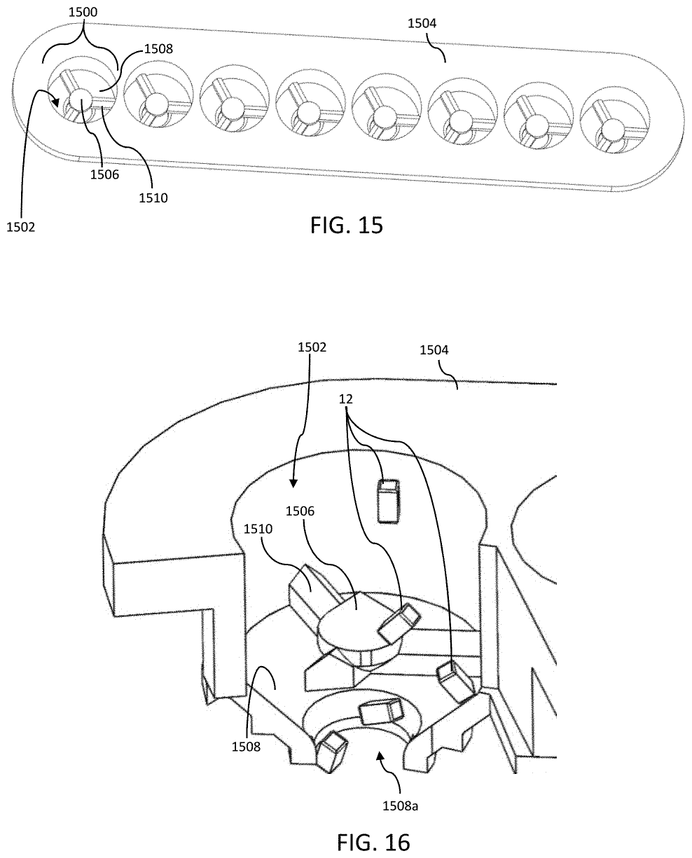

In view of the above, and in another embodiment, a decelerator can be arranged outside the final collection container (e.g., tray 96) and be provided as a 3-dimensional passageway (e.g., cylindrical in shape) that introduces convex and/or concave damping surfaces to the path of travel of sorted components 12. Above the entry of the decelerator, the components 12 are typically traveling through round tubes (e.g., the ejection tubes 84). The components 12 are smaller than the tube size, and thus travel through the ejection tubes 84 across a wide range of trajectories. Referring to FIG. 15, a decelerator 1500 can be provided within an opening 1502 of a decelerator body 1504. The opening 1502 can be sized so such that an end of the of an ejection tube 84 can be secured therein (e.g., by interference fit between an exterior of the ejection tube 84 and the sidewall of the opening 1502. The top of each decelerator 1500 has a conical tip 1506 that is in the path of travel of any components 12 traveling or crossing through the center of the area of travel. Further down within the decelerator 1500, a concave outer wall 1508 intercepts any components 12 that avoided contact with the convex tip 1504. In this way, all components 12 will receive at least one deceleration event before falling through a discharge opening 1508a defined by the concave outer wall 1508. The conical tip 1506 may be suspended over the discharge opening 1508a by one or more beams 1510 extending from the sidewall of the opening 1502. As shown in FIG. 15, a plurality of decelerators 1500 may be integrally formed within a common decelerator body 1504. Additionally, the shape and location of the conical tip 1506, concave outer wall 1508, and beam 1510 are such that the components 12 will typically encounter multiple deceleration events, improving the effectiveness of the decelerator 1500. The decelerator 1500 exemplarily shown in FIGS. 15 and 16 has the following key feature advantages over the prior art:

1. Compact design in relation to the path of travel of the components 12. Prior-used designs were composed of a series of flaps which required several stages in order to efficiently decelerate components 12 passing through with a wide range of trajectories.

2. No obstruction within the final collection container (e.g., bin 94) for the components 12. Deceleration function is not hindered by how full the collection container is.

3. True 3-dimensional deceleration functionality. All components that pass through the decelerator 1500 will contact at least 1 surface of one or more of the conical tip 1506, concave outer wall 1508, and beam(s) 1510.

4. A wide range of materials including plastic, virtually all elastomers, or foam rubber, or coatings of the same on a rigid substrate, can be used to form the above-described structures of the decelerator 1500.

5. The decelerator body 1502 can be quickly and simply replaced, as it will wear out in normal use due to frequent impact from the components 12.

6. Easy to alter the geometry to better suit the characteristics of a variety of sorted components such as (size or mass density) as well as relevant operating parameters of the sorting system (dwell time within a sort cycle, air pressure used to eject components).

### VI. CONCLUSION

The foregoing is illustrative of embodiments and examples of the invention, and is not to be construed as limiting thereof. Although a few specific embodiments and examples have been described with reference to the drawings, those skilled in the art will readily appreciate that many modifications to the disclosed embodiments and examples, as well as other embodiments, are possible without materially departing from the novel teachings and advantages of the invention. Accordingly, all such modifications are intended to be included within the scope of the invention as defined in the claims. For example, skilled persons will appreciate that the subject matter of any sentence, paragraph, example or embodiment can be combined with subject matter of some or all of the other sentences, paragraphs, examples or embodiments, except where such combinations are mutually exclusive. The scope of the present invention should, therefore, be determined by the following claims, with equivalents of the claims to be included therein.

What is claimed is:

1. An electrical component testing apparatus, comprising:
a vacuum plate including:
a first surface;
a second surface opposite the first surface; and
a plurality of through-holes extending through the vacuum plate from the first surface to the second surface;
a manifold arranged at the second surface of the vacuum plate, the manifold including:
a manifold body; and
a plurality of passageways extending within the manifold body, wherein each of the plurality of passageways includes a first end and a second end, wherein the first end includes an opening that intersects an exterior of the manifold body at a first location corresponding to a location of a through-hole in the vacuum plate and wherein the second end includes an opening that intersects an exterior of the manifold body at a second location; and
a source of pressurized air coupled to the opening of the second end.

2. The apparatus of claim 1, wherein at least one of the plurality of passageways has a length that is at least substantially equal to the length of at least one other of the plurality of passageways.

3. The apparatus of claim 1, wherein the manifold body is formed of a visually transparent material.

4. The apparatus of claim 1, wherein at least one selected from the group consisting of the first end and the second end further includes an annular channel formed in the exterior surface of the manifold body and extending around the opening.

5. The apparatus of claim 4, further comprising a seal arranged within the annular channel.

6. The apparatus of claim 1, further comprising a test plate arranged on the first surface of the vacuum plate, wherein the test plate includes a plurality of through-holes and wherein the test plate is moveable relative to the vacuum plate such that at least some of the plurality of through-holes in the test plate and alignable to the plurality of through-holes in the vacuum plate.

7. The apparatus of claim 6, wherein the test plate is configured to retain a plurality of electrical components.

8. The apparatus of claim 6, wherein the plurality of through-holes in the test plate are configured to retain a plurality of electrical components.

9. The apparatus of claim 8, wherein the electrical component is an MLCC chip.

10. The apparatus of claim 8, further comprising:
a plurality of tube assemblies each having a first end and a second end opposite the first end, wherein the second end is lower than the first end, wherein the first end of each of the plurality of tube assemblies is configured to receive at least some of the plurality of electrical components and each of the plurality of tube assemblies is configured such that received electrical components can travel therethrough along a path of travel; and
a decelerator body having a plurality of openings formed therein, wherein each of the plurality of openings is in fluid communication with a corresponding second end of each of the plurality of tube assemblies to receive electrical components traveling through the plurality of tube assemblies; and
a decelerator arranged within each of the plurality of openings, wherein the decelerator is configured to decelerate the electrical components received within a corresponding one of the plurality of openings.

11. The apparatus of claim 10, wherein the second end of each of the plurality of tube assemblies is inserted into a corresponding opening formed in the decelerator body.

12. The apparatus of claim 10, further comprising a bin arranged beneath a decelerator within at least one of the plurality of openings, wherein the bin is configured to receive electrical components discharged by the decelerator.

13. A decelerator for an electrical component testing apparatus having a tube assembly with a first end and a second end opposite the first end, wherein the second end is lower than the first end, wherein the first end is configured to receive a plurality of electrical components and the tube assembly is configured such that received electrical components can travel therethrough along a path of travel, the decelerator comprising:
a decelerator body having an opening formed therein, the opening having a first end as a second end opposite the first end; and
a structure defining a convex surface within the opening and facing toward first end of the opening; and
a concave surface arranged below the structure.

14. The decelerator of claim 13, wherein the concave surface defines the second end of the opening.
